(19) United States
(12) Patent Application Publication
(10) Pub. No.: US 2003/0122123 A1
(43) Pub. Date: Jul. 3, 2003

(54) Method and apparatus for determining parasitic capacitances in an integrated circuit

(75) Inventors: Xiaowei Deng, Plano, TX (US); James David Gallia, McKinney, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/039,484

(22) Filed: Dec. 31, 2001

(51) Int. Cl. H01L 23/58

(52) U.S. Cl. 257/48

(57) ABSTRACT

A method of determining a capacitance for use in a circuit simulation is provided. The method may include determining a test structure capacitance of a test structure, simulating a design structure, extracting a design structure capacitance of the simulated design structure, and calculating a parasitic capacitance of the design structure. Calculating the parasitic capacitance may comprise deducting the test structure capacitance from the design structure capacitance.

### TECHNICAL FIELD OF THE INVENTION

This invention relates in general to determining capacitances and, more particularly, to a method and apparatus for determining parasitic capacitances in an integrated circuit.

### BACKGROUND OF THE INVENTION

As integrated circuits have progressively become more complex, increasing emphasis has been placed on techniques for simulating the operation of integrated circuits and devices incorporating such integrated circuits. Simulation techniques may include, for example, the use of computer simulation programs. To perform such simulations, particular input must be determined for the simulation.

For example, particular capacitances must be determined in order to simulate an integrated circuit. An integrated circuit typically includes a number of circuit components, such as transistors for example, as well as interconnections between those circuit components. The circuit includes capacitances internal to the devices, commonly referred to as device capacitances, as well as capacitances external to the devices referred to as parasitic capacitances, or which may also be referred to as wire capacitances or interconnect capacitances. Parasitic capacitances, which can negatively affect the operation of the integrated circuit, include capacitances between a device and an interconnection, and capacitances between interconnections. Typically, the device capacitances and parasitic capacitances must both be determined, or extracted, to perform an accurate simulation of the integrated circuit.

### SUMMARY OF THE INVENTION

In accordance with the present invention, a method and apparatus for determining parasitic capacitances in an integrated circuit are provided that substantially eliminate or reduce the disadvantages and problems associated with previously developed methods and apparatuses.

According to one embodiment, a method of determining a capacitance for use in a circuit simulation is provided. The method includes determining a test structure capacitance of a test structure, simulating a design structure, extracting a design structure capacitance of the design structure, and calculating a parasitic capacitance of the design structure. Calculating the parasitic capacitance comprises deducting the test structure capacitance from the design structure capacitance.

According to another embodiment, an apparatus for simulating the operation of a circuit is provided. The apparatus includes a computer system that includes a processor and a memory that stores computer program code executable by the processor. The computer program code includes a circuit simulator program that receives input regarding a component of the circuit. The input comprises a device model and a parasitic capacitance of a design structure of the component. The parasitic capacitance is determined using a test structure capacitance associated with a test structure and a design structure capacitance associated with the design structure. The processor is operable to execute the circuit simulator program to output performance characteristics of the circuit based at least in part on the parasitic capacitance and the description of the design structure.

Various embodiments of the present invention may benefit from numerous technical advantages. It should be noted that one or more embodiments may benefit from some, none, or all of the advantages discussed below.

One technical advantage of the invention is that a parasitic capacitance of a transistor having a particular design structure may be estimated or determined without physically manufacturing or fabricating the particular design structure.

Another technical advantage is that a parasitic capacitance may be determined that is a good approximation of the actual parasitic capacitance of a transistor. In particular, the estimated parasitic capacitance may be more accurate than a parasitic capacitance estimated without using a test structure capacitance. Also, an accurate estimated parasitic capacitance may be determined for a transistor within a cell having relatively large devices, such as a ring oscillator, whose operation strongly depends on the parasitic gate-to-drain (Cgd) capacitance.

Another technical advantage is that a parasitic capacitance may be determined such that the sum of the parasitic capacitance and a device capacitance of a transistor structure is a total capacitance that is an good approximation of the actual total capacitance of a transistor structure.

Another technical advantage is that a series of test structure capacitances or parasitic capacitances as a function of a pre-determined parameter may be generated and used for determining other test or design structure capacitances or parasitic capacitances. For example, a series of estimated parasitic capacitances as a function of contact-to-gate spacing and contact-to-contact spacing may be generated. Similarly, a series of parasitic capacitances as a function of one or more structural boundary conditions may be generated.

Another technical advantage is that the time and/or expense associated with accurately determining or estimating the parasitic capacitance of a transistor is reduced or minimized. For example, time and/or expense may be reduced or minimized because it is not necessary to physically manufacture or fabricate a transistor having a particular design structure. In addition, time and/or expense may be reduced or minimized by selecting or determining particular capacitances from stored capacitance data, eliminating the need to fabricate or simulate a particular transistor structure.

Another technical advantage is that the method or methods of determining the estimated parasitic capacitances may be used to assess the accuracy of other methods used to determine parasitic capacitances.

In addition, in some embodiments a test structure may be provided having calibrated boundary conditions such that a simulated test structure capacitance extracted from the test structure is a good approximation of an empirical test structure capacitance determined by physically testing the test structure. Thus, it is possible to estimate the simulated capacitance of a test structure by physically testing the test structure, without actually simulating the test structure. This provides a technical advantage since such elaborate simulations, such as for example device simulators, are often time-consuming and expensive.

Other technical advantages will be readily apparent to one skilled in the art from the following figures, descriptions, and claims.

### BRIEF DESCRIPTION OF THE DRAWINGS

For a more complete understanding of the present invention and for further features and advantages, reference is now made to the following description, taken in conjunction with the accompanying drawings, in which:

FIG. 1 illustrates an electronic device in accordance with an embodiment of the present invention;

FIG. 2 is a diagrammatic, cross-sectional, side view of a transistor test structure in accordance with an embodiment of the present invention;

FIG. 3 is a diagrammatic, cross-sectional, side view of a transistor design structure in accordance with an embodiment of the present invention;

FIG. 4 illustrates a method of determining a parasitic gate-to-drain (Cgd) capacitance for use in a circuit simulation in accordance with an embodiment of the present invention;

FIG. 4a illustrates a method of calibrating a test structure to be used in determining gate-to-drain (Cgd) capacitances in accordance with an embodiment of the present invention;

FIG. 5 illustrates a method of determining a total gate-to-drain (Cgd) capacitance of a design structure in accordance with an embodiment of the present invention;

FIG. 6 illustrates an apparatus for simulating the operation of a circuit in accordance with an embodiment of the present invention; and

FIG. 7 illustrates the operation of a circuit simulator program that uses a parasitic gate-to-drain (Cgd) capacitance determined in accordance with an embodiment of the present invention.

### DETAILED DESCRIPTION OF THE DRAWINGS

FIG. 1 illustrates an electronic apparatus and includes a detailed view of a section of a circuit board within the electronic apparatus. An electronic apparatus 10 includes a circuit board 12 upon which a circuit 14 is located. Circuit 14 includes a plurality of circuit wires 16 and at least one circuit device, such as a microchip 18. Microchip 18 includes an integrated circuit 20 and a plurality of leads 22 that electrically connect integrated circuit 20 to circuit wires 16. Integrated circuit 20 includes at least one integrated circuit component 24, such as a transistor, capacitor, resistor, or any other component, that may be included in an integrated circuit. Electronic apparatus 10 may be any type of electronic apparatus that includes at least one integrated circuit 20, such as, for example, a personal computer, mainframe, stand-alone processor, telecommunications device, PDA, radio, or any component thereof. The present invention may be incorporated into other electronic devices.

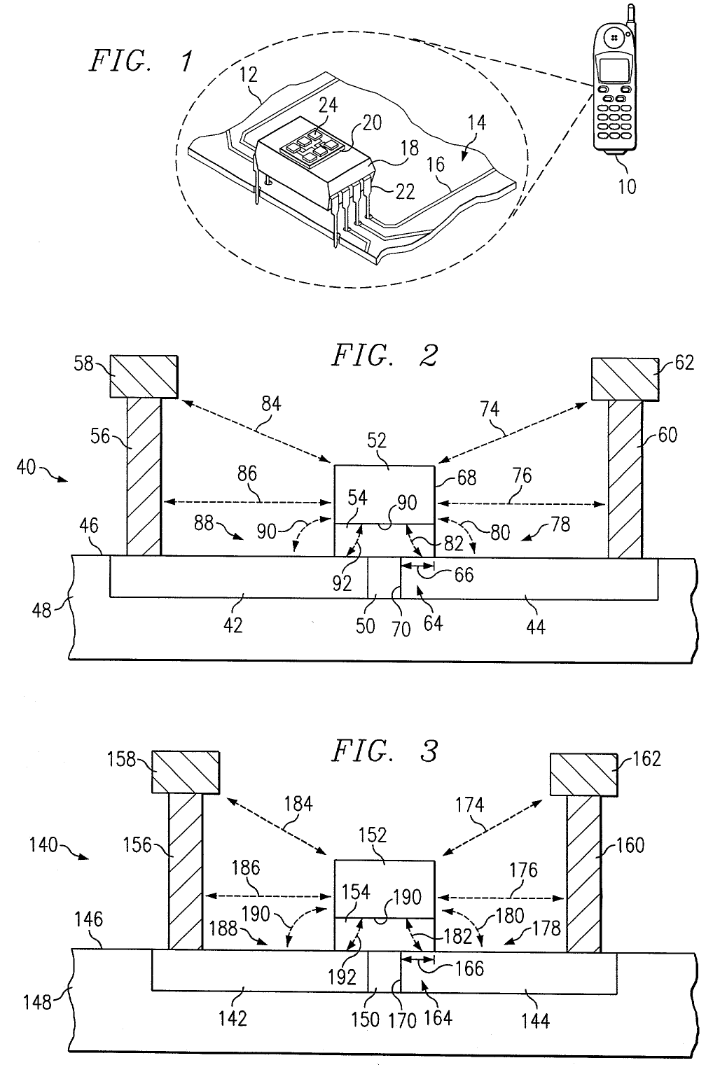

In one embodiment, integrated circuit component 24 is a transistor that may have a variety of structures. FIG. 2 is a diagrammatic cross-sectional side view of a transistor test structure 40. It should be noted that FIG. 2 is an approximated representation of an actual transistor structure. Therefore, FIG. 2 might not accurately represent all of the elements of a transistor or the correct dimensions of a transistor. Transistor test structure 40 includes an active source region 42 representing a transistor source and an active drain region 44 representing a transistor drain, each formed in a top surface 46 of a silicon semiconductor substrate, or body, 48 using known doping methods. A channel region 50 of body 48 separates active source region 42 from active drain region 44. Transistor test structure 40 also includes a gate 52 made of a polysilicon material, and a gate oxide layer 54 of silicone dioxide disposed between gate 52 and body 48.

Transistor test structure 40 may also include a source contact 56, a source metal 58, a drain contact 60, and a drain metal 62. Source contact 56 and drain contact 60 are formed from a conductive material such as tungsten, and are in electrical contact with active source region 42 and active drain region 44, respectively. Source metal 58 and drain metal 62 are formed from a conductive material such as aluminum, and are in electrical contact with source contact 56 and drain contact 60, respectively.

Transistor test structure 40 may be defined in part by one or more boundary conditions 64. Boundary conditions 64 include dimensions of and spatial relationships between various elements of transistor test structure 40. In particular, boundary conditions 64 may be focused in the area around gate 52 and active source and drain regions 42 and 44. For example, boundary conditions 64 may include the thickness of gate oxide layer 54, an overlap 66 defined by the distance that a side surface 68 of gate 52 overlaps a side surface 70 of active drain region 44, and the distance between gate 52 and body 48.

When an electrical current is applied to a transistor, electrical capacitances are generated. As shown in FIG. 2, these capacitances include a gate-to-metal capacitance 74 between gate 52 and drain metal 62, a gate-to-contact capacitance 76 between gate 52 and drain contact 60, and a gate-to-active capacitance 78 between gate 52 and active drain region 44. Gate-to-active capacitance 78 may include a fringing capacitance 80 between side surface 68 of gate 52 and active drain region 44, and an overlap capacitance 82 between a bottom surface 90 of gate 52 and active drain region 44.

Similarly, capacitances are generated between gate 52 and active source region 42, source contact 56, and source metal 58. These capacitances include a gate-to-metal capacitance 84, a gate-to-contact capacitance 86, and a gate-to-source capacitance 88. In addition, similar to gate-to-active capacitance 78, gate-to-source capacitance 88 may include a fringing capacitance 90 and an overlap capacitance 92.

Since transistor test structure 40 as shown in FIG. 2 is symmetrical, capacitances 74, 76 and 78 are theoretically identical to capacitances 84, 86 and 88, respectively. Thus, although the following discussion focuses on the drain side of transistor test structure 40, the discussion applies equally to the source side of transistor test structure 40. However, it should be noted that in some embodiments (not expressly shown), transistor test structure 40 may be asymmetrical, and thus capacitances 74, 76 and 78 may be different from capacitances 82, 86 and 88.

FIG. 3 is a diagrammatic, cross-sectional, side view of a transistor design structure 140. As with FIG. 2, it should be noted that FIG. 3 is an approximated representation of an actual transistor structure. It should also be noted that certain elements of FIG. 3 (that are not expressly mentioned below) that correspond to elements of FIG. 2 have reference numerals that are 100 greater than their corresponding FIG. 2 elements. For example, source metal 158 shown in FIG. 3 corresponds with source metal 58 shown in FIG. 2.

Although transistor design structure 140 includes many of the same basic elements as transistor test structure 40 shown in FIG. 2, transistor design structure 140 may have one or more different dimensions or boundary conditions than transistor test structure 40. In particular, the distance between contact 160 and gate 152 in transistor design structure 140 may be different from the distance between contact 60 and gate 52 in transistor test structure 40.

Due to such differences in the dimensions of transistor design structure 140 and transistor test structure 40, the various capacitances associated with structures 140 and 40 may be different as well. For example, in one embodiment in which contact 160 is closer to gate 152 than contact 60 is to gate 52, gate-to-metal capacitance 174 and gate-to-contact capacitance 176 are greater than gate-to-metal capacitance 74 and gate-to-contact capacitance 76, respectively. In addition, in this embodiment, gate-to-active capacitance 178 is less than gate-to-active capacitance 78 since some amount of capacitance between the gate and the drain active may be transferred to the capacitance between the gate and the drain contact and/or metal as the drain contacts and metals are disposed closer to the gate, such as with transistor design structure 140 as compared to transistor test structure 40.

In one embodiment, one or more boundary conditions 164 associated with transistor design structure 140 are substantially similar to corresponding boundary conditions 64 of transistor test structure 40. Boundary conditions 164 include the amount of overlap 166, the thickness of gate oxide layer 154, and the distance between active drain region 144 and body 148. Overlap capacitance 182 is based at least in part on boundary conditions 164, just as overlap capacitance 82 is based at least in part on boundary conditions 64. In one embodiment, boundary conditions 164 are substantially similar to boundary conditions 64 such that overlap capacitance 182 is substantially similar to overlap capacitance 82.

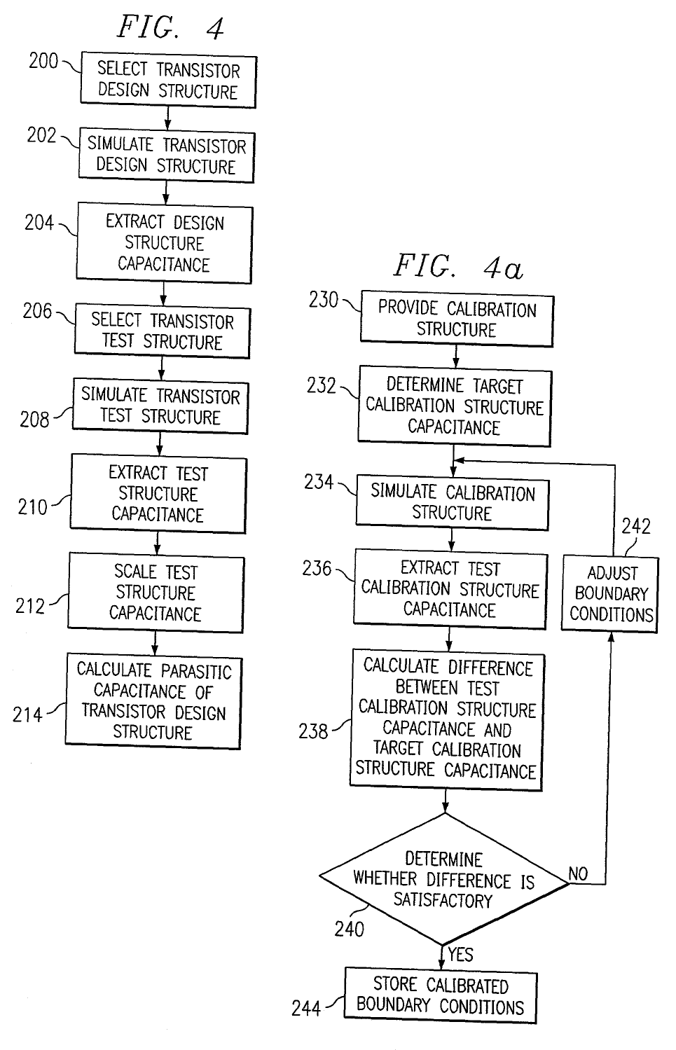

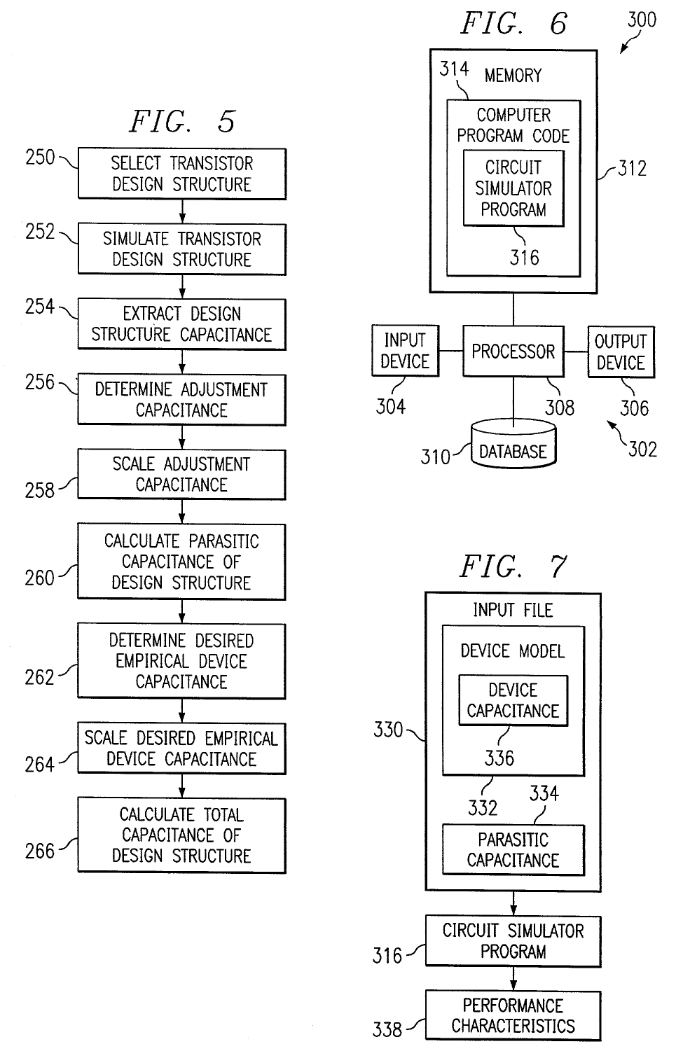

According to some embodiments of the present invention, a parasitic gate-to-drain, or Cgd, capacitance (Cgd_{design}_{_{—}}ₚₐᵣ) of transistor design structure 140 is determined, as described below with reference to FIGS. 4, 4a, and 5. In particular, the parasitic Cgd capacitance (Cgd_{design}_{_{—}}ₚₐᵣ) may be determined by scaling and subtracting a simulated test structure Cgd capacitance (Cgdₜₑₛₜ_{_{—}}ₛᵢₘ) from a simulated design structure Cgd capacitance (Cgd_{design}_{_{—}}ₛᵢₘ). Thus, the parasitic Cgd capacitance may be written as:

Cgd_{design}_{_{—}}ₚₐᵣ=Cgd_{design}_{_{—}}ₛᵢₘ−Cgdₜₑₛₜ_{_{—}}ₛᵢₘ (1)

In addition, in some embodiments, a total Cgd capacitance (Cgd_{design}_{_{—}}ₜₒₜₐₗ) of transistor design structure 140 may be determined using the methods described below. In particular, the total Cgd capacitance (Cgd_{design}_{_{—}}ₜₒₜₐₗ) may be determined by adding an empirically measured test structure Cgd capacitance (Cgdₜₑₛₜ_{_{—}}ₑₘₚ) to the parasitic Cgd capacitance (Cgd_{design}_{_{—}}ₚₐᵣ) as follows:

Cgd_{design}_{_{—}}ₜₒₜₐₗ=Cgd_{design}_{_{—par}}+Cgdₜₑₛₜ_{_{—}}ₑₘₚ (2)

Equations (1) and (2) can be combined and rewritten as follows:

Cgd_{design}_{_{—}}ₜₒₜₐₗ=Cgd_{design}_{_{—}}ₛᵢₘ−Cgdₜₑₛₜ_{_{—}}ₛᵢₘ+Cgdₜₑₛₜ_{_{—}}ₑₘₚ (3)

The total Cgd capacitance of transistor design structure 140 (Cgd_{design}_{_{—}}ₜₒₜₐₗ) determined according to some embodiments of the present invention may be an accurate estimate of the theoretical, or actual, Cgd capacitance of transistor design structure 140, which is the equal to the sum of capacitances 174, 176 and 178.

FIG. 4 illustrates a method of determining a parasitic Cgd capacitance for use in a circuit simulation in accordance with the present invention. At step 200, a particular transistor design structure 140 is selected. Transistor design structure 140 may be selected having one or more particular boundary conditions 164, and one or more other physical dimensions. For example, transistor design structure 140 may be selected having a particular contact-to-gate spacing, defined by a distance between contact 160 and gate 152, and/or a particular contact-to-contact spacing, defined by a distance between contact 160 and a nearby drain contact located along a direction perpendicular to the cutting plane of the cross-section of structures 40 and 140, respectively.

At step 202, transistor design structure 140 is simulated, or modeled. Transistor design structure 140 may be simulated using a computer, for example using simulation software. It should be noted that transistor design structure 140 may be modeled using any technique suitable for modeling a physical structure.

At step 204, a design structure Cgd capacitance (Cgd_{design}_{_{—}}ₛᵢₘ) is extracted, or determined, from the simulated transistor design structure 140 using a simulator. The design structure Cgd capacitance may include simulated capacitances 174, 176, and 178. The design structure Cgd capacitance may be extracted using a three-dimensional simulator, such as a three-dimensional capacitance field solving simulator. In one embodiment, the design structure Cgd capacitance is extracted using a 3D Raphael simulator. However, it should be noted that the design structure Cgd capacitance may be extracted using any technique suitable for extracting a capacitance.

At step 206, a particular transistor test structure 40 is selected. In one embodiment, transistor test structure 40 is selected based on one or more boundary conditions 164 associated with transistor design structure 140. In a particular embodiment, transistor test structure 40 is selected such that boundary conditions 64 of transistor test structure 40 are substantially similar to boundary conditions 164 of transistor design structure 140. This may be done to avoid or minimize differences between overlap capacitance 82 and overlap capacitance 182 in order to determine an accurate parasitic Cgd capacitance associated with transistor design structure 140. In another embodiment, transistor test structure 40 is selected based on one or more other physical dimensions associated with transistor design structure 140. For example, transistor test structure 40 may be selected based on the contact-to-gate spacing and/or contact-to-contact spacing in transistor design structure 140 selected at step 200. In a particular embodiment, transistor test structure 40 is selected such that the contact-to-gate spacing and/or contact-to-contact spacing in transistor test structure 40 are substantially similar to the contact-to-gate spacing and/or contact-to-contact spacing 164 in transistor design structure 140.

In some embodiments, transistor test structure 40 is selected based on a calibration of the structure, as described below with reference to FIG. 4a. In these embodiments, transistor test structure 40 is selected having one or more boundary conditions 64 which are identical or substantially similar to boundary conditions of a calibration structure, as described below with reference to FIG. 4a.

At step 208, transistor test structure 40 is simulated, or modeled. As with transistor design structure 140 simulated in step 202 above, transistor test structure 40 may be simulated using a computer, for example using simulation software. It should be noted that transistor test structure 40 may be modeled using any technique suitable for modeling a physical structure.

At step 210, a test structure Cgd capacitance (Cgdₜₑₛₜ_{_{—}}ₛᵢₘ) is extracted, or determined, from the simulated or modeled transistor test structure 40 using a simulator. The extracted test structure Cgd capacitance may include simulated capacitances 74, 76, and 78. The test structure Cgd capacitance may be extracted using a three-dimensional simulator, such as a three-dimensional capacitance field solving simulator. In one embodiment, the test structure Cgd capacitance is extracted using a 3D Raphael simulator. However, it should be noted that the test structure Cgd capacitance may be extracted using any technique suitable for extracting a capacitance.

In an alternative embodiment, an empirical test structure Cgd capacitance (Cgdₜₑₛₜ_{_{—}}ₑₘₚ) is determined by physically testing the test structure. In this embodiment, transistor test structure 40 might not be simulated or modeled as in step 208.

Alternatively, the test structure Cgd capacitance may be determined by selecting a capacitance from a plurality of test structure capacitances. For example, in one embodiment, the test structure Cgd capacitance is selected from a plurality of empirical Cgd test structure capacitances based on transistor design structure 140. In this embodiment, each empirical test structure Cgd capacitance may be determined by physically testing one of a plurality of different transistor test structures.

In another embodiment, the test structure Cgd capacitance is selected, based on transistor design structure 140, from a plurality of simulated test structure Cgd capacitances. In this embodiment, each test structure Cgd capacitance may be extracted from one of a plurality of different transistor test structures using an elaborate capacitance simulator. For example, the elaborate capacitance simulator may be a device simulator which may be incapable of simulating complex structures, such as three-dimensional structures, or structures of a particular scale.

At step 212, the test structure Cgd capacitance is scaled based on the relationship between a scaling dimension of transistor test structure 40 and a scaling dimension of transistor design structure 140. In one embodiment, the test structure Cgd capacitance is scaled based on the relationship between the width of gate 52 of transistor test structure 40 and the width of gate 152 of transistor design structure 140. For example, if the width of gate 52 is twice the width of gate 152, the test structure Cgd capacitance is scaled by dividing the test structure Cgd capacitance by a factor of two. It should be noted that the width of gates 52 and 152 is measured along a direction perpendicular to the cutting plane of the cross-section of structures 40 and 140, respectively.

At step 214, a parasitic Cgd capacitance (Cgd_{design}_{_{—}}ₚₐᵣ) of transistor design structure 140 is calculated based on or using the scaled test structure Cgd capacitance and the design structure Cgd capacitance. In one embodiment, the parasitic Cgd capacitance is calculated by deducting the scaled test structure Cgd capacitance from the design structure Cgd capacitance (see Equation 1). However, the step of calculating the parasitic Cgd capacitance using both the scaled test structure Cgd capacitance and the design structure Cgd capacitance may be done using other techniques or may include one or more sub-steps within the scope of the present invention.

Thus, using the methods described above, the parasitic Cgd capacitance (Cgd_{design}_{_{—}}ₚₐᵣ) of a transistor having a particular transistor design structure may be determined or estimated without physically manufacturing or fabricating the transistor design structure. In one embodiment, the parasitic Cgd capacitance is an accurate approximation of the actual parasitic Cgd capacitance of a transistor having the particular design structure. In particular, the parasitic Cgd capacitance may be more accurate than a parasitic Cgd capacitance determined or estimated without using a capacitance extracted from a simulated transistor test structure. For example, the parasitic Cgd capacitance of a transistor within a memory cell may be accurate to within 1-2%. In addition, an accurate parasitic Cgd capacitance may be determined for a transistor within a cell having relatively large devices, such as compared to the size of devices in a memory cell. For example, the parasitic Cgd capacitance of a transistor within a ring oscillator, such as a C035.1 ring oscillator manufactured by Texas Instruments, may be accurate to within 1-2%.

In addition, steps 200 through 212 may be repeated using a variety of transistor design structures to generate a set of parasitic Cgd capacitances. For example, parasitic Cgd capacitances may be determined for a variety of transistor design structures having different contact-to-gate spacing, defined by a distance between contact 160 and gate 152, and/or different contact-to-contact spacing, defined by a distance between contact 160 and a nearby drain contact located along a direction perpendicular to the cutting plane of the cross-section of structures 40 and 140, respectively.

In one embodiment, this method is used to generate a series of parasitic Cgd capacitances as a function of contact-to-gate spacing and contact-to-contact spacing. Similarly, parasitic Cgd capacitances may be determined for a variety of transistor design structures having one or more different boundary conditions 164 to generate a series of parasitic Cgd capacitances as a function of one or more boundary conditions 164.

FIG. 4a illustrates a method of calibrating a test structure to be used in determining Cgd capacitances in accordance with the present invention. In step 230, a calibration structure is provided that comprises one or more boundary conditions. The calibration structure may be a transistor structure similar to transistor test structure 40, and the one or more boundary conditions may include such boundary conditions as boundary conditions 64 as described above with reference to FIG. 2.

At step 232, a target calibration structure Cgd capacitance of the calibration structure is determined. In one embodiment, the target calibration structure Cgd capacitance is determined by physically testing the calibration structure to obtain an empirical Cgd capacitance. In another embodiment, the target calibration structure Cgd capacitance is determined by simulating or modeling the calibration structure and extracting the target calibration structure Cgd capacitance of the simulated calibration structure using a simulator.

The simulator used to extract the target calibration structure Cgd capacitance may be more elaborate or more accurate than the simulator used to extract the design structure Cgd capacitance and/or the test structure capacitance as described above with reference to steps 204 and 210, respectively, shown in FIG. 4. In addition, the simulator used to extract the target calibration structure Cgd capacitance may be more elaborate or more accurate than the simulator used to extract a test calibration structure Cgd capacitance, as described below with reference to step 236. For example, the simulator used to extract the target calibration structure Cgd capacitance may be a device simulator which may be incapable of simulating complex structures, such as three-dimensional structures, or structures of a particular scale.

At step 234, the calibration structure is simulated or modeled, such as described above with reference to step 208 in FIG. 4.

At step 236, a test calibration structure Cgd capacitance is extracted, or determined, from the simulated calibration structure using a simulator. The test structure Cgd capacitance may be extracted or determined as described above with reference to step 210 in FIG. 4. In one embodiment, the simulator used to extract the test calibration structure Cgd capacitance is less elaborate or less accurate than the simulator used to extract the target calibration structure Cgd capacitance. In a particular embodiment, the simulator used to extract the test calibration structure Cgd capacitance is the same simulator used to extract the design structure Cgd capacitance and the test structure capacitance as described above with reference to steps 204 and 210, respectively, shown in FIG. 4.

At step 238, the difference between the test calibration structure Cgd capacitance and the target calibration structure Cgd capacitance is calculated. At step 240, it is determined whether the difference calculated at step 238 is satisfactory according to an accuracy criterion. For example, the accuracy criterion may specify a maximum allowable difference as a discrete value or as a percentage of the test calibration structure Cgd capacitance or the target calibration structure Cgd capacitance.

If it is determined at step 240 that the difference is unsatisfactory according to the accuracy criterion, at least one of the one or more boundary conditions of the calibration structure is adjusted at step 242. For example, if one of the boundary conditions is the amount of overlap between an edge of the gate and an edge of an active drain region, and the difference was determined to be unsatisfactory at step 238, one or more dimensions of the calibration structure may be modified such that the amount of overlap is adjusted. In one embodiment, the adjusted boundary condition or boundary conditions may be adjusted by predetermined increments.

Steps 234 through 242 may be repeated until it is determined at step 240 that the difference between the test calibration structure Cgd capacitance and the target calibration structure Cgd capacitance is satisfactory. At this point, the boundary conditions may be considered calibrated and may be stored in a boundary condition data set at step 244.

The calibrated boundary conditions may be used when providing or selecting a test structure used to determine a parasitic or total Cgd capacitance of a design structure, such as the test structures used in the methods described in FIGS. 4 and 5. For example, in the method shown in FIG. 4, a test structure may be selected at step 206 that has boundary conditions 64 that are identical or substantially similar to boundary conditions calibrated according to the methods discussed with reference to FIG. 4a. Using this technique provides a test structure for which a simulated test structure Cgd capacitance extracted using a simulator is a good approximation of an empirical test structure Cgd capacitance determined by physically testing the test structure. Thus, it is possible to estimate the simulated Cgd capacitance of a test structure by physically testing the test structure without actually simulating the test structure. This may be advantageous since such simulations are often time-consuming and expensive.

FIG. 5 illustrates a method of determining a total Cgd capacitance (Cgd_{design}_{_{—}}ₜₒₜₐₗ) of a design structure in accordance with the present invention. At step 250, a particular transistor design structure (such as design structure 140, for example) at least partially defined by one or more design structure parameters is selected. The design structure parameters may include one or more boundary conditions and/or one or more dimensions associated with the selected design structure. For example, the selected transistor design structure may have a particular contact-to-gate spacing and/or a particular contact-to-contact spacing.

At step 252, the transistor design structure is simulated, or modeled. The transistor design structure may be simulated or modeled as described above with reference to step 202 in FIG. 4.

At step 254, a design structure Cgd capacitance (Cgd_{design}_{_{—}}ₛᵢₘ) is extracted, or determined, from the simulated transistor design structure. The design structure Cgd capacitance may include capacitances such as previously-described capacitances 174, 176, and 178. The design structure Cgd capacitance may be extracted or determined as described above with reference to step 204 in FIG. 4.

At step 256, an adjustment Cgd capacitance is determined based on the one or more design structure parameters and a set of test structure data. The set of test structure data comprises information regarding a plurality of transistor test structures (such as previously-described test structure 40, for example) having various test structure parameters, such as boundary conditions or other physical dimensions. For example, the selected transistor test structure may have a particular contact-to-gate spacing and/or a particular contact-to-contact spacing.

The information may include, for each transistor test structure, a test structure Cgd capacitance and information regarding the parameters of the particular transistor test structure. In one embodiment, the test structure Cgd capacitance of each transistor test structure is determined by simulating each transistor test structure and extracting a test structure Cgd capacitance, such as described above with reference to steps 208 and 210 in FIG. 4. In another embodiment, the test structure Cgd capacitance of each transistor test structure is an empirical Cgd capacitance determined by physically testing each transistor test structure. In the embodiment shown in FIG. 5, the information includes for each test structure both an empirical Cgd capacitance determined by physical testing and a test structure Cgd capacitance determined by simulation and extraction as described above.

Thus, the test structure data may comprise a series or an array of scaled test structure Cgd capacitances as a function of different test structure parameters, such as the boundary conditions and/or other physical dimensions such as contact-to-gate spacing and contact-to-contact spacing. The test structure data may be stored in a chart, table, graph, or any other format. In one embodiment, the test structure data is stored electronically by a computer.

The adjustment Cgd capacitance may be determined from the test structure data based on a particular design structure parameter or parameters. In particular, if the test structure data includes information regarding a test structure having parameters which match the particular parameters of the design structure, the adjustment Cgd capacitance would be determined to be the test structure Cgd capacitance associated with that test structure would determine. Alternatively, if the test structure data does not include information for a test structure having parameters which match the particular parameters of the design structure, the adjustment Cgd capacitance may be approximated using an algorithm. For example, the test structure data may be approximated by interpolation, extrapolation, or using some other algorithm suitable to approximate a value based on a series or array of data.

At step 258, the adjustment Cgd capacitance is scaled such as described with reference to step 212 in FIG. 4. In an alternative embodiment, the test structure Cgd capacitances in the test structure data are scaled before the adjustment Cgd capacitance is determined.

At step 260, a parasitic Cgd capacitance (Cgd_{design}_{_{—}}ₚₐᵣ) of the transistor design structure is calculated based on or using the scaled adjustment Cgd capacitance and the design structure Cgd capacitance. In one embodiment, the parasitic Cgd capacitance is calculated by deducting the adjustment Cgd capacitance from the design structure Cgd capacitance. This may be illustrated by Equation 1, where the adjustment Cgd is substituted for Cgdₜₑₛₜ_{_{—}}ₛᵢₘ. However, the step of calculating the parasitic Cgd capacitance may be accomplished using other techniques or may include one or more sub-steps within the scope of the present invention.

At step 262, a desired empirical device Cgd capacitance (Cgdₜₑₛₜ_{_{—}}ₑₘₚ) is determined based on the one or more design structure parameters and the set of test structure data. In other words, the desired empirical device Cgd capacitance may be determined from the test structure data based on one or more particular design structure parameters. In particular, if the test structure data includes information regarding a test structure having parameters which match the particular parameters of the design structure, the empirical device Cgd capacitance associated with that test structure would determine the adjustment Cgd capacitance. Alternatively, if the test structure data does not include information for a test structure having parameters which match the particular parameters of the design structure, the desired empirical device Cgd capacitance may be approximated using an algorithm. For example, the test structure data may be approximated by interpolation, extrapolation, or using some other algorithm suitable to approximate a value based on a series or array of data.

At step 264, the desired empirical device Cgd capacitance (Cgdₜₑₛₜ_{_{—}}ₑₘₚ) is scaled such as described with reference to step 212 in FIG. 4. In an alternative embodiment, the empirical device Cgd capacitances in the test structure data are scaled before the desired empirical device Cgd capacitance is determined.

At step 266, a total Cgd capacitance (Cgd_{design}_{_{—}}ₜₒₜₐₗ) of the design structure is calculated based on or using the parasitic Cgd capacitance and the desired empirical device Cgd capacitance. In one embodiment, the total Cgd capacitance, Cgd_{design}_{_{—}}ₜₒₜₐₗ, is calculated by adding the parasitic Cgd capacitance, Cgd_{design}_{_{—}}ₚₐᵣ, to the desired empirical device Cgd capacitance, Cgdₜₑₛₜ_{_{—}}ₑₘₚ (see Equation 2). However, the step of calculating the total Cgd capacitance may be accomplished using other techniques or may include one or more sub-steps within the scope of the present invention.

The methods of determining or estimating parasitic and total Cgd capacitances described above with reference to FIGS. 4 and 5 may be used in the design of integrated circuits, such as memory cells or logic cells. In particular, the parasitic and/or total Cgd capacitances determined or estimated using the methods described above may be used by circuit simulators for designing such integrated circuits, as described in further detail below with reference to FIGS. 6 and 7 In addition, the methods described above may reduce or minimize the time and/or expense associated with accurately determining or estimating the parasitic and/or total Cgd capacitance associated with a transistor structure. In particular, time and/or expense may be reduced or minimized because it is not necessary to physically manufacture or fabricate a transistor having a particular design structure.

In addition, the methods described above may be used to assess the accuracy of other methods used to determine or estimate a parasitic Cgd capacitance associated with a transistor structure or other integrated circuit component.

FIG. 6 illustrates an apparatus 300 for simulating the operation of a circuit that includes a parasitic Cgd capacitance determined according to the present invention. Apparatus 300 includes a computer system 302 that comprises an input device 304, an output device 306, a processor 308, a database 310, and a memory 312. Input device 304 may include a pointing device such as a mouse, a track pad, a keyboard, and the like. Also, input device 304 may include a combination of these devices. Output device 306 may include a monitor, a printer, and the like, or any combination of these devices.

It will be understood that computer system 302 may be otherwise configured within the scope of the present invention. For example, computer system 302 may operate as a stand-alone system or may operate as a client-server networked system. Also, computer system 302 may operate in a network environment such as a LAN, WAN, intranet, extranet, or Internet.

Database 310 includes computer records that may be generally identified by tables. It will be understood that the computer records may be otherwise combined and/or divided within the scope of the present invention.

Memory 312 includes computer program code 314 that may be executed by processor 308. It will be understood that computer program code 314 may be combined and/or divided for processing in any suitable manner within the scope of the present invention. Also, while only one processor is depicted, it should be understood that computer system 302 may comprise multiple processors. Further, any appropriate software platform may be utilized including functional or object-oriented programming.

Computer program code 314 may be loaded into memory 312 from disk storage (not explicitly shown). Disk storage may include a variety of types of storage media. For example, disk storage may include floppy disk drives, hard disk drives, CD-ROM drives, or magnetic tape drives. In one embodiment, computer program code 314 comprises a circuit simulator program 316 operable to simulate the operation of an electrical circuit, such as an integrated circuit.

FIG. 7 illustrates the operation of circuit simulator program 316. Circuit simulator program 316 receives an input file 330 including information regarding a particular transistor. In particular, input file 330 comprises a device description, or device model, 332 and a parasitic Cgd capacitance 334 associated with a particular design structure of the transistor.

Parasitic Cgd capacitance 334 may be determined using the methods discussed above with reference to FIGS. 4 and 5. In particular, parasitic Cgd capacitance 334 may be determined using a test structure Cgd capacitance and a design structure Cgd capacitance as described regarding FIG. 4, or using a desired test structure Cgd capacitance and a design structure Cgd capacitance as described regarding FIG. 5.

Parasitic Cgd capacitance 334 may be determined from a graph, look-up table, or other form of stored data, and may be determined by circuit simulator program 316 or otherwise using computer system 302. In a particular embodiment, parasitic Cgd capacitance 334 is selected from or determined using a series or array of parasitic Cgd capacitances as a function of one or more transistor structure parameter, such as one or more boundary conditions or other dimensions, such as contact-to-gate spacing and contact-to-contact spacing. Such a series or array of parasitic Cgd capacitances may be generated using the methods discussed above with reference to FIGS. 4 and 5.

Device model 332 includes a definition of the transistor and a device Cgd capacitance 336 associated with a particular test structure of the transistor. In one embodiment, device Cgd capacitance 336 may be physically or empirically measured from the test structure. In another embodiment, device Cgd capacitance 336 is obtained from a graph, look-up table, or other form of stored data regarding test structure Cgd capacitances. In another embodiment, device Cgd capacitance 336 is effectively set at zero.

In one embodiment, device Cgd capacitance 336 and parasitic Cgd capacitance 334 may be combined to define an estimated total Cgd capacitance of a transistor having the particular design structure. It is an advantage of this embodiment that the estimated total Cgd capacitance is an accurate approximation of the true total Cgd capacitance of a transistor having the particular design structure, such as could be obtained by empirical testing of such as transistor. In particular, the estimated total Cgd capacitance may be more accurate than a total Cgd capacitance estimated without using a Cgd capacitance extracted from a simulated transistor test structure. In one embodiment in which device Cgd capacitance 336 is effectively set at zero, the estimated total Cgd capacitance of the transistor is equal to parasitic Cgd capacitance 334.

In an alternative embodiment, input file 330 comprises a total Cgd capacitance of a transistor having the particular design structure. The total Cgd capacitance may be determined from a graph, look-up table, or other form of stored data, and may be determined by circuit simulator program 316 or otherwise using computer system 302. In a particular embodiment, the total Cgd capacitance is selected from or determined using a series or array of total Cgd capacitances as a function of one or more transistor structure parameter, such as one or more boundary conditions or other dimensions, such as contact-to-gate spacing and contact-to-contact spacing. Such a series or array of total Cgd capacitances may be generated using the methods discussed above with reference to FIGS. 4 and 5.

Although a transistor is discussed above, it should be noted that input file 330 may alternately or further comprise similar information regarding an integrated circuit component other than a transistor, such as a resistor or capacitor, and may include a plurality or a combination of such integrated circuit components.

Input file 330 is received by circuit simulator program 316, which uses the information in input file 330 to simulated the operation of an integrated circuit. Circuit simulator program 316 may output one or more performance characteristics 338 from the simulation of the integrated circuit, such as the speed, power, timing, cross-talk, soft-error rates (SER), or electromagnetism (EM) associated with the integrated circuit.

In one embodiment, circuit simulator program 316 is a SPICE simulator that includes a netlist as input. The netlist includes parasitic Cgd capacitance 334 determined according to any of the methods described above. However, it should be noted that circuit simulator program 316 may be any type of simulator operable to simulate the operation of an electrical circuit, for example MicroSim's PSPICE, Avanti's HSPICE or Star-Sim, Cadence's Spectre(r), or Synopsis' TimeMill(r), or Mentor Graphics' Accusim or Accusim II.

It should be noted that although the Cgd capacitances discussed above with reference to FIGS. 3, 4, 4a, 5, and 7 concerned capacitances on the drain side of the transistors, the discussion may apply equally to capacitances on the source side of the transistors. In particular, in one embodiment, Cgd capacitances include capacitances on the source side of the transistors, such as capacitances 84, 86 and 88 associated with test structure 40 and capacitances 184, 186 and 188 associated with test structure 140. In another embodiment, Cgd capacitances include capacitances on the both sides of the transistors, such as capacitances 74, 76, 78, 84, 86 and 88 associated with test structure 40 and capacitances 174, 176, 178, 184, 186 and 188 associated with test structure 140.

Although an embodiment of the invention and its advantages are described in detail, a person skilled in the art could make various alternations, additions, and omissions without departing from the spirit and scope of the present invention as defined by the appended claims.

What is claimed is:

1. A method of determining a capacitance for use in a circuit simulation, the method comprising:
determining a test structure capacitance of a test structure;
simulating a design structure;
extracting a design structure capacitance of the design structure; and
calculating a parasitic capacitance of the design structure, wherein calculating the parasitic capacitance comprises deducting the test structure capacitance from the design structure capacitance.

2. The method of claim 1, wherein determining the test structure capacitance comprises:
providing a test structure;
simulating the test structure; and
extracting a test structure capacitance of the simulated test structure.

3. The method of claim 2, wherein the step of extracting the test structure capacitance comprises using three-dimensional capacitance field solving.

4. The method of claim 1, wherein determining the test structure capacitance comprises physically testing the test structure.

5. The method of claim 1, wherein determining the test structure capacitance comprises selecting, based on the design structure, a test structure capacitance from a plurality of empirical test structure capacitances, each empirical test structure capacitance being determined by physically testing one of a plurality of different test structures.

6. The method of claim 1, wherein determining the test structure capacitance comprises selecting, based on the design structure, the test structure capacitance from a plurality of simulated test structure capacitances, each test structure capacitances being extracted from one of a plurality of different test structures using an elaborate capacitance simulator.

7. The method of claim 1, wherein the step of extracting the design structure capacitance comprises using three-dimensional capacitance field solving.

8. The method of claim 1, further comprising:
determining an empirical device capacitance by physically testing the test structure; and
calculating a total capacitance of the design structure, wherein calculating the total capacitance comprises adding the parasitic capacitance to the empirical device capacitance.

9. The method of claim 1, wherein the test structure comprises a gate, a source-drain active area, a contact, and a metal, and wherein the test structure capacitance comprises a gate to source-drain capacitance between the gate and the source-drain active area, a gate to contact capacitance between the gate and the contact, and a gate to metal capacitance between the gate and the metal.

10. The method of claim 1, further comprising scaling the test structure capacitance based on at least one scaling dimension associated with the design structure.

11. The method of claim 10, wherein the design structure comprises a gate, and wherein the at least one scaling dimension comprises the width of the gate.

12. The method of claim 1, wherein the step of providing the test structure comprises selecting the test structure based on one or more geometric boundary conditions associated with the design structure.

13. The method of claim 12, wherein the design structure comprises a gate and a source-drain active area, and wherein the geometric boundary conditions include the amount of overlap between the gate and the source-drain active area.

14. The method of claim 12, wherein the design structure comprises a gate oxide layer, and wherein the geometric boundary conditions include the thickness of the gate oxide layer.

15. The method of claim 12, wherein the design structure comprises a body and a source-drain active area, and wherein the geometric boundary conditions include the spacing between the body and the source-drain active area.

16. The method of claim 1, further comprising:
providing a calibration structure having one or more boundary conditions;
determining a target calibration structure capacitance of the calibration structure;
simulating the calibration structure;
extracting a test calibration structure capacitance of the simulated calibration structure using a first simulator;
calculating the difference between the test calibration structure capacitance and the target calibration structure capacitance;
determining if the difference is satisfactory according to an accuracy criterion; and
adjusting at least one of the one or more boundary conditions if the difference is unsatisfactory according to the accuracy criterion; and
wherein determining the test structure capacitance comprises determining the test structure capacitance of a test structure having boundary conditions which match the boundary conditions of the calibration structure, including any adjusted boundary conditions.

17. The method of claim 16, wherein the step of determining the test structure capacitance comprises:
providing a test structure having boundary conditions which match the boundary conditions of the calibration structure, including any adjusted boundary conditions;
simulating the test structure; and
extracting a test structure capacitance of the simulated test structure;
wherein the test structure capacitance and the design structure capacitance are extracted using the first simulator.

18. The method of claim 16, wherein the target calibration structure capacitance is determined by physically testing the calibration structure.

19. The method of claim 16, wherein the target calibration structure capacitance is determined by:
simulating the calibration structure; and
extracting a calibration structure capacitance of the simulated calibration structure using a second simulator.

20. The method of claim 19, wherein the second simulator is an elaborate capacitance simulator.

21. A method of determining a capacitance for use in a circuit simulation, the method comprising:
selecting a test structure based on one or more geometric boundary conditions associated with a design structure, the test structure comprising a gate, a source-drain active area, a contact, and a metal;
simulating the test structure;
extracting a test structure capacitance of the simulated test structure, the test structure capacitance comprising a gate to source-drain capacitance between the gate and the source-drain active area, a gate to contact capacitance between the gate and the contact, and a gate to metal capacitance between the gate and the metal;
simulating the design structure;
extracting a design structure capacitance of the simulated design structure; and
scaling the test structure capacitance based on at least one scaling dimension associated with the design structure; and
calculating a parasitic capacitance of the design structure, wherein calculating the parasitic capacitance comprises deducting the test structure capacitance from the design structure capacitance.

22. The method of claim 21, wherein the at least one scaling dimension comprises the width of the gate.

23. The method of claim 21, wherein the geometric boundary conditions include the amount of overlap between the gate and the source-drain active area.

24. The method of claim 21, wherein the design structure comprises a gate oxide layer, and wherein the geometric boundary conditions include the thickness of the gate oxide layer.

25. The method of claim 21, wherein the design structure comprises a body, and wherein the geometric boundary conditions include the spacing between the body and the source-drain active area.

26. A method of determining a capacitance for use in a circuit simulation, the method comprising:
selecting a design structure at least partially defined by one or more design structure parameters;
determining a design structure capacitance of the design structure;
determining a desired test structure capacitance based on the one or more design structure parameters and the test structure data, a set of test structure data including information regarding a plurality of test structures, the information including a test structure capacitance and one or more test structure parameters associated with each of the plurality of test structures; and
calculating a parasitic capacitance of the design structure, wherein calculating the parasitic capacitance comprises deducting the desired test structure capacitance from the design structure capacitance.

27. The method of claim 26, wherein:
the design structure comprises a design structure gate and a design structure contact, and the one or more design structure parameters comprises a distance between the design structure gate and the design structure contact; and
each of the plurality of test structures comprises a test structure gate and a test structure contact, and the one or more test structure parameters associated with each of the plurality of test structures comprises a distance between the test structure gate and the test structure contact.

28. The method of claim 26, wherein:
the design structure comprises a design structure first contact and a design structure second contact, and the one or more design structure parameters comprises a distance between the design structure first contact and the design structure second contact; and
each of the plurality of test structures comprises a test structure first contact and a test structure second contact, and the one or more test structure parameters associated with each of the plurality of test structures comprises a distance between the test structure first contact and the test structure second contact.

29. The method of claim 26, wherein the test structure capacitance associated with each of the plurality of test structures is determined by:
simulating each test structure;
extracting a test structure capacitance of each simulated test structure; and
scaling each test structure capacitance based on at least one scaling dimension associated with the design structure.

30. The method of claim 29, wherein the step of extracting each test structure capacitance comprises using three-dimensional capacitance field solving.

31. The method of claim 29, the test structure data further including an empirical device capacitance associated with each of the plurality of test structures determined by physically testing each of the test structures, wherein the method further includes:
determining a desired empirical device capacitance based on the one or more design structure parameters and the test structure data; and
calculating a total capacitance of the design structure, wherein calculating the total capacitance comprises adding the parasitic capacitance to the select empirical device capacitance.

32. The method of claim 26, wherein the test structure capacitance associated with each of the plurality of test structures is determined by physically testing each test structure.

33. The method of claim 26, wherein the design structure capacitance is determined by:
simulating the design structure; and
extracting a design structure capacitance of the simulated design structure.

34. The method of claim 33, wherein the step of extracting the design structure capacitance comprises using three-dimensional capacitance field solving.

35. The method of claim 26, wherein at least one of the one or more design structure parameters is different from at least one of the one or more test structure parameters associated with each of the plurality of test structures, and wherein determining the desired test structure capacitance comprises using an algorithm to a desired test structure capacitance.

36. An apparatus for simulating the operation of a circuit, the apparatus comprising a computer system which includes a processor and a memory that stores computer program code executable by the processor, the computer program code comprising a circuit simulator program which receives input regarding a component of the circuit, the input comprising a device model and a parasitic capacitance of a design structure of the component, the parasitic capacitance being determined using a test structure capacitance associated with a test structure and a design structure capacitance associated with the design structure, wherein the processor is operable to execute the circuit simulator program to output performance characteristics of the circuit based at least in part on the parasitic capacitance and the device model of the design structure.

37. The apparatus of claim 36, wherein the parasitic capacitance received as input by the simulator program is determined by deducting the test structure capacitance from the design structure capacitance

38. The method of claim 36, wherein the test structure capacitance is determined by:
simulating the test structure; and
extracting a test structure capacitance of the simulated test structure.

39. The method of claim 38, wherein the test structure capacitance is determined by physically testing the test structure.

40. The method of claim 36, wherein the design structure capacitance is determined by:
simulating the design structure; and
extracting a design structure capacitance of the simulated design structure.

41. The apparatus of claim 36, wherein the device model received as input by the simulator program includes an empirical device capacitance of the test structure obtained by physically testing the test structure.

42. The apparatus of claim 36, wherein the device model received as input by the simulator program includes a device capacitance of the test structure, and wherein the device capacitance is effectively set at zero.

43. The apparatus of claim 36, wherein the test structure used to calculate the parasitic capacitance is selected based on one or more geometric boundary conditions associated with the design structure.

44. The apparatus of claim 36, wherein the memory further stores parasitic capacitance data accessible by the processor, the parasitic capacitance data comprising a plurality of parasitic capacitances each corresponding to one of a plurality of structures, wherein the parasitic capacitance received as input into the simulator program is selected from the plurality of parasitic capacitances based on one or more parameters of the design structure.

45. The apparatus of claim 44, wherein the design structure comprises a gate and a contact, and wherein the parameters of the design structure include the spacing between the first contact and the gate.

46. The apparatus of claim 44, wherein the design structure comprises a first contact and a second contact, and wherein the parameters of the design structure include the spacing between the first contact and the second contact.

47. An electronic apparatus, at least a portion of the electronic apparatus designed using a circuit simulation, the circuit simulation receiving a parasitic capacitance of a design structure, the parasitic capacitance determined by:
providing a test structure;
simulating the test structure;
extracting a test structure capacitance of the simulated test structure;
simulating a design structure;
extracting a design structure capacitance of the simulated design structure; and
calculating a parasitic capacitance of the design structure, wherein calculating the parasitic capacitance comprises deducting the test structure capacitance from the design structure capacitance.

48. The electronic apparatus of claim 47, wherein the circuit simulation further receives a device model of a design structure, the device model including an empirical design structure capacitance of the design structure obtained by physically testing the design structure.

49. The electronic apparatus of claim 47, further comprising selecting the test structure based on one or more geometric boundary conditions associated with the design structure.
